(19) United States
(12) Patent Application Publication
(10) Pub. No.: US 2025/0070724 A1
(43) Pub. Date: Feb. 27, 2025

(54) ENVELOPE FREQUENCY AND HARMONICS TERMINATION FOR RF AMPLIFIERS

(71) Applicant: pSemi Corporation, San Diego, CA (US)

(72) Inventors: Shota ISHIHARA, SAN DIEGO, CA (US); Tero Tapio RANTA, SAN DIEGO, CA (US)

(21) Appl. No.: 18/454,683

(22) Filed: Aug. 23, 2023

(51) Int. Cl. H03F 1/32; H03F 3/195

(52) U.S. Cl. CPC H03F 1/32; H03F 3/195; H03F 2200/165; H03F 2200/451

(57) ABSTRACT

Methods and devices for termination of an envelope frequency and harmonics in an RF amplifier are presented. A multifunctional filter is coupled to an RF node of the RF amplifier to provide first and second conduction paths between the RF node and first/second low impedance nodes. The first conduction path provides a low impedance at the envelope frequency and high impedances at an operating frequency of the RF amplifier and corresponding higher order harmonics. The second conduction path provides a low impedance at the higher order harmonics and high impedances at the envelope frequency and at the operating frequency. The multifunctional filter includes first/second inductors in series connection between the RF node and the first low impedance node. According to one aspect, the first/second inductors are coupled to first/second capacitors to respectively form a tank circuit and a trap circuit operating at the frequencies of the harmonics.

### TECHNICAL FIELD

The present disclosure is related to electronic circuits, and more particularly to use of a multifunctional filter for reducing intermodulation distortion products in an RF amplifier.

### BACKGROUND

FIG. 1A shows a prior art (single-stage) radio frequency (RF) amplifier (100a) that may be used, for example, in a transmitter (e.g., power amplifier) or receiver (e.g., low noise amplifier) frontend portion of an RF communication system. The RF amplifier (100a) may include an amplifier stage (110) that includes at least one transistor, M1, configured as a common-source device or amplifier, the amplifier stage (110) configured to receive an input RF signal, RF_{IN}, at an input node, N_{IN}, of the amplifier stage (110) and output a corresponding amplified output RF signal, RF_{OUT}, at an output node, N_{OUT}, of the amplifier stage (110). Biasing of the amplifier stage (110) may be provided by a supply voltage, Vdd, coupled to the output node, N_{OUT}, through an inductor (e.g., L_{D}, choke) and referenced to a reference ground coupled to (e.g., the source of) the transistor, M1. Respective input and output nodes, N_{IN} and N_{OUT}, of the amplifier stage (110) may be coupled to respective input and output matching circuits, MN_{IN} and MN_{OUT}, in order to reduce impedance mismatches to respective coupled circuits.

As shown in FIG. 1B, the amplifier stage (110) of the prior art RF amplifier (100a) may include a plurality of series connected transistors (M1, M2, . . . , Mp), including the input transistor, M1, configured as a common-source device, and one or more cascode transistors (M2, . . . , Mp), each configured as a common-gate device. Biasing of the transistors of the amplifier stage may be provided by respective biasing circuits (e.g., BM1, BM2, . . . , BMp) that may be coupled to the gates of the respective transistors (M1, M2, . . . , Mk) via, for example, respective series connected resistors (R1, R2, . . . . Rp).

During operation, nonlinearities and/or distortion in the prior art RF amplifier (100a) may generate intermodulation products that may negatively impact a performance metric (as measured by a performance parameter, e.g., error vector magnitude, EVM) of the RF amplifier (100a). Such nonlinearities and/or distortion may also be coupled to the RF amplifier (100a) by other amplification stages coupled to (the input of) the RF amplifier (100a) and therefore further amplified by the RF amplifier (100a). In particular, such intermodulation products may include an upper and a lower sideband of a channel (e.g., frequency range) being processed/amplified and may produce, for example in cases of high-power operation and/or wider modulation schemes of the RF signal (e.g., baseband modulation width, baseband bandwidth, envelope signal bandwidth) being processed, sideband asymmetries due to differing magnitudes of the upper and lower sidebands.

FIG. 1C shows an exemplary mechanism for generation of sideband asymmetries by considering two tones/frequencies (f₁, f₂) of an RF channel operating at a center frequency, f₀, having a modulation width Δf (e.g., f₂-f₁, baseband bandwidth). As shown in the graph of FIG. 1C, during processing/amplification of the two tones/frequencies, f₁ and f₂, corresponding higher order harmonics, 2f₁ and 2f₂, may be generated which in turn may combine with the (lower frequency) baseband frequency components, (f₂-f₁) and (f₁-f₂), present at either sides of the zero frequency, to produce respective upper band and lower band third order intermodulation (IMD₃) products, (2f₂-f₁) and (2f₁-f₂). Because the lower band IMD₃, (2f₁-f₂), may be based on the (negative) baseband frequency component (f₁-f₂) and the upper band IMD₃, (2f₂-f₁), may be based on the (positive) baseband frequency component (f₂-f₁), then as shown in FIG. 1C, a sideband asymmetry having a (nonzero) magnitude of ΔIMD₃ may be generated.

Some prior art teachings may include L-C filter circuits coupled to the RF amplifier in order to short (to ground) the baseband frequency components (e.g., f₂-f₁ and f₁-f₂). However, because the baseband frequency may have a wide bandwidth (e.g., up to about 320 MHz with newer modulation schemes) and may include very low frequency components (e.g., 100's to 1000's of Hz), realization of the proposed L-C filter circuits may include capacitors having physical sizes that may not be suitable for integration in an integrated circuit.

The above prior art shortcomings are a basis for the teachings according to the present disclosure, including a multifunctional filter aimed to reduce sideband asymmetries by targeting higher order harmonics as well as baseband frequency components while using components with sufficiently small physical sizes for integration in an integrated circuit.

### SUMMARY

According to a first aspect of the present disclosure, a circuit is presented, comprising: a radio frequency (RF) amplifier configured to amplify an RF signal; and a multifunctional filter coupled to an RF node of the RF amplifier, wherein the multifunctional filter comprises: a first conduction path between the RF node and a first low impedance node, the first conduction path configured to isolate the RF signal and corresponding higher order harmonics at the RF node from the first low impedance node and pass an envelope signal at the RF node to the first low impedance node; and a second conduction path between the RF node and a second low impedance node, the second conduction path configured to isolate the RF signal and envelope signal at the RF node from the second low impedance node and pass the higher order harmonics at the RF node to the second low impedance node.

According to a second aspect of the present disclosure, a method for reducing intermodulation distortion products in a radio frequency (RF) amplifier is presented, the method comprising: coupling a first conduction path between an RF node of the RF amplifier and a first low impedance node, the first conduction path configured to isolate an RF signal and corresponding higher order harmonics at the RF node from the first low impedance node and pass an envelope signal at the RF node to the first low impedance node, thereby terminating the envelope signal at the first low impedance node; and coupling a second conduction path between the RF node and a second low impedance node, the second conduction path configured to isolate the RF signal and envelope signal at the RF node from the second low impedance node and pass the higher order harmonics at the RF node to the second low impedance node, thereby terminating the higher order harmonics at the second low impedance node; thereby reducing the intermodulation distortion products based on the terminating of the envelope signal and the terminating of the higher order harmonics.

Further aspects of the disclosure are provided in the description, drawings and claims of the present application.

### BRIEF DESCRIPTION OF DRAWINGS

The accompanying drawings, which are incorporated into and constitute a part of this specification, illustrate one or more embodiments of the present disclosure and, together with the description of example embodiments, serve to explain the principles and implementations of the disclosure.

FIG. 1A shows a simplified schematic of a prior art RF amplifier including at least one transistor.

FIG. 1B shows a simplified schematic of a prior art RF amplifier including a plurality of transistors.

FIG. 1C shows a graph representative of upper and lower sideband intermodulation products generated during operation of an RF amplifier.

FIG. 2A shows a simplified schematic of a multifunctional filter according to the present disclosure coupled to an RF amplifier.

FIG. 2B shows a simplified schematic of a plurality of multifunctional filters according to the present disclosure coupled to respective input and output nodes of an RF amplifier.

FIG. 2C shows a simplified schematic of a plurality of multifunctional filters according to the present disclosure coupled to respective internal nodes of an RF amplifier.

FIG. 2D and FIG. 2E show simplified schematics of a multifunctional filter according to the present disclosure configured to couple a node of an RF amplifier to exemplary low impedance nodes.

FIG. 3A shows coupling of a high frequency filter to a low frequency filter of the multifunctional filter according to the present disclosure.

FIG. 3B shows exemplary embodiments according to the present disclosure of the low frequency and high frequency filters of FIG. 3A.

FIG. 3C shows further exemplary embodiments according to the present disclosure of the low frequency and high frequency filters of FIG. 3A.

FIG. 3D shows an exemplary embodiment of the multifunctional filter according to the present disclosure based on the configuration of FIG. 3B.

FIG. 4A shows exemplary implementations of two series connected inductors for use in the multifunctional filter according to the present disclosure.

FIG. 4B shows the exemplary implementations of the two series connected inductors according to FIG. 4A applied to the exemplary multifunctional filter of FIG. 3B.

FIG. 5 show simplified schematics of a multifunctional filter of FIG. 4B configured to couple an output node of an RF amplifier to exemplary low impedance nodes.

FIG. 6 is a process chart showing various steps of a method according to an embodiment of the present disclosure for reducing intermodulation distortion products in a radio frequency (RF) amplifier.

Like reference numbers and designations in the various drawings indicate like elements.

### DETAILED DESCRIPTION

Throughout the present disclosure, embodiments and variations are described for the purpose of illustrating uses and implementations of inventive concepts of various embodiments. The illustrative description should be understood as presenting examples of the inventive concept, rather than as limiting the scope of the concept as disclosed herein.

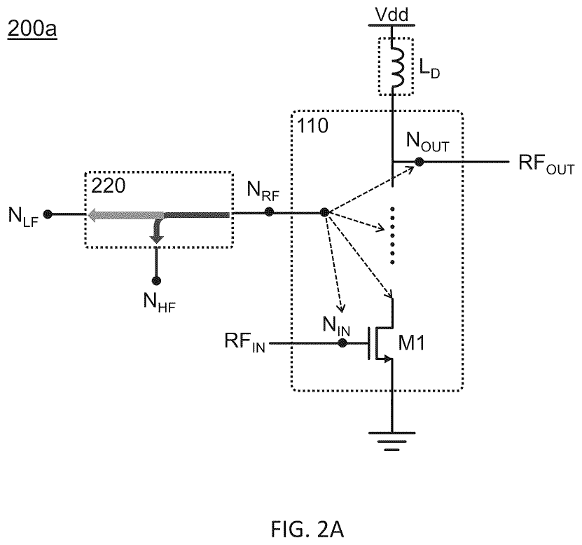

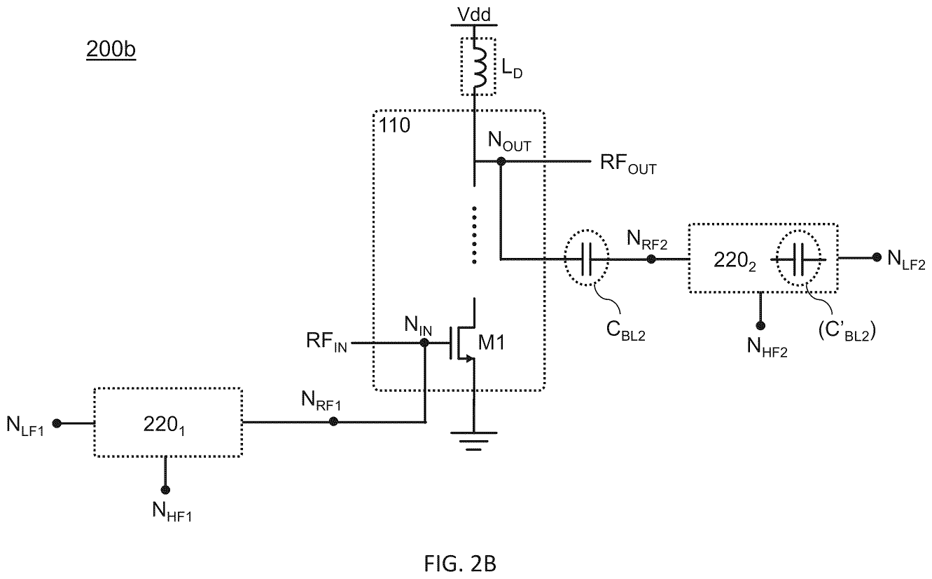

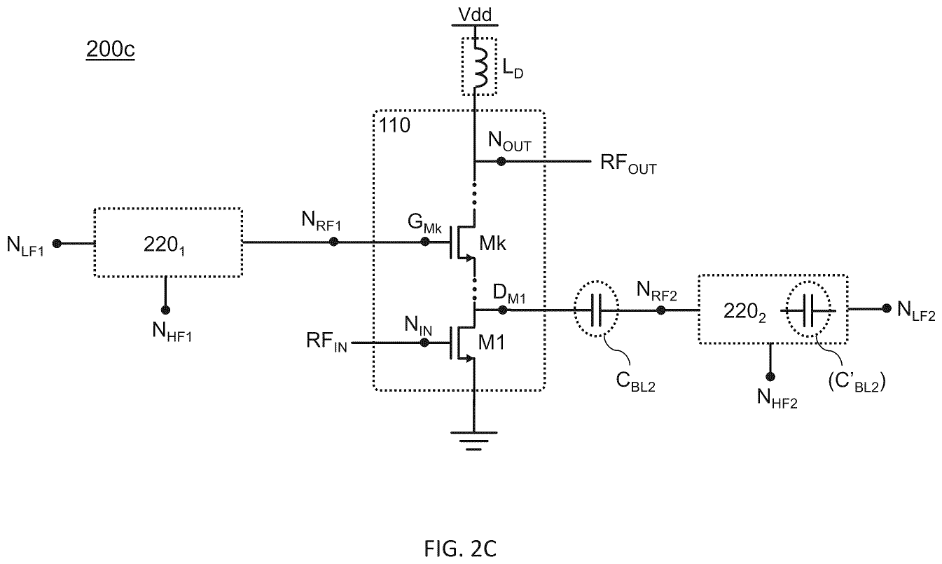

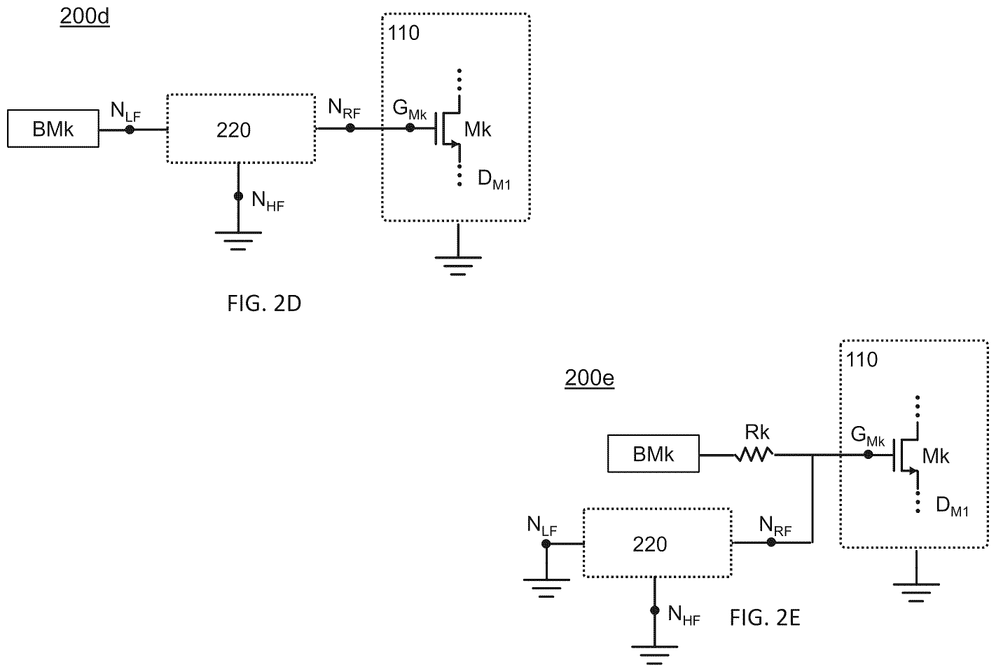

FIG. 2A shows a simplified schematic of a circuit (200a) comprising a multifunctional filter (220, e.g., a multi-band filter) according to the present disclosure coupled to an RF amplifier (e.g., amplifier stage 110). In particular, as shown in FIG. 2A, a node N_{RF} of the multifunctional filter (220) may couple to an RF carrying node, also referred herein as an RF node, of the amplifier stage (110), such as, for example, the input node, N_{IN}, the output node, N_{OUT}, or any other internal node of the amplifier stage (110). The multifunctional filter (220) according to the present disclosure further comprises two low impedance nodes, N_{LF} and N_{HF}, or in other words, nodes N_{LF} and N_{HF} are configured to be coupled to (or are presented with) low impedances (at distinct frequency ranges later described). Accordingly, the multifunctional filter (220) may provide a first conduction path (N_{RF}, N_{LF}) between the nodes N_{RF} and N_{LF}, and a second conduction path (N_{RF}, N_{HF}) between the nodes N_{RF} and N_{HF}. It should be noted that the multifunctional filter (220) according to the present disclosure may be considered as a three-terminal circuit block, having three terminals respectively provided at nodes N_{RF}, N_{LF}, and N_{HF}.

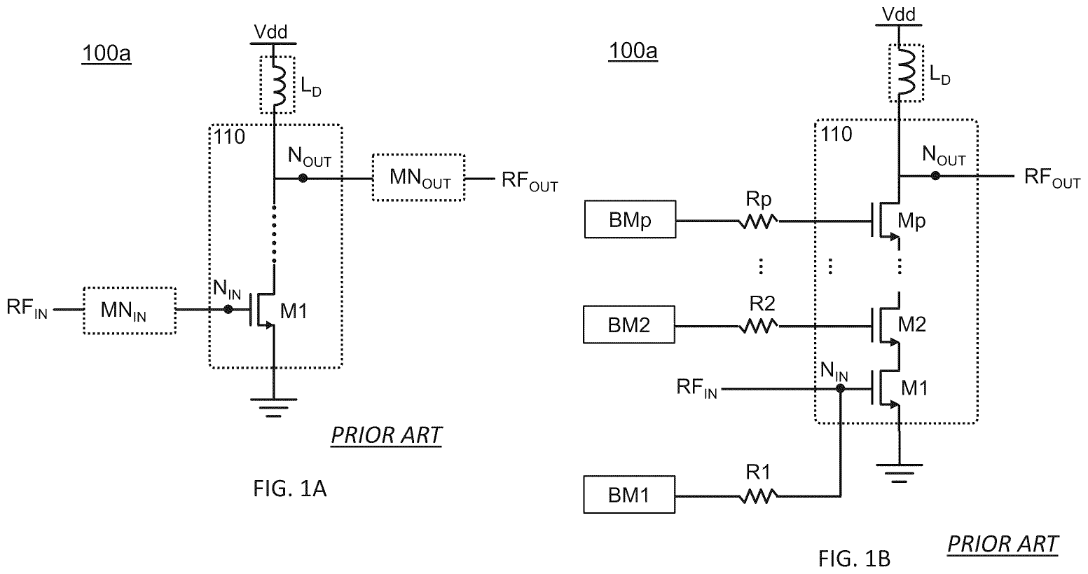

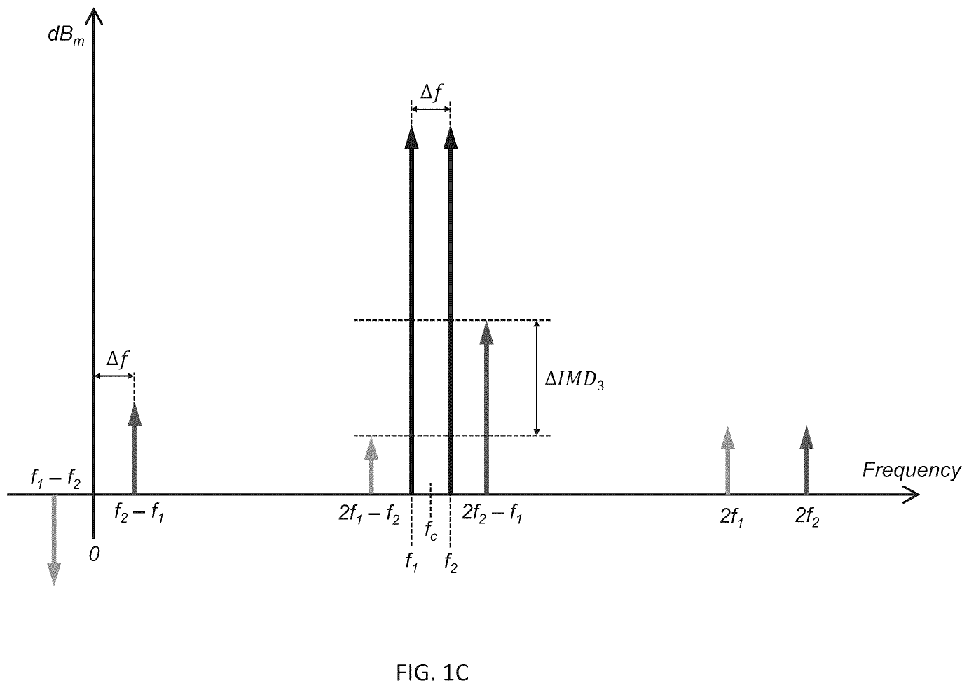

With further reference to FIG. 2A, the first conduction path (N_{RF}, N_{LF}) may provide an impedance (e.g., tunable impedance) that is sufficiently low at a frequency range of the envelope signal (i.e., the low baseband frequency range, Δf, about the zero frequency of FIG. 1C) that may pass the envelope signal from the node N_{RF} to the low impedance node N_{LF} (substantially) unaltered, thereby terminating the envelope signal by the low impedance node N_{LF} (e.g., low impedance at the baseband frequency range). Furthermore, the first conduction path (N_{RF}, N_{LF}) may provide an impedance that is sufficiently high at a frequency range of operation of the RF signal (e.g., Δf about the center/fundamental frequency, f₀, of FIG. 1C) that may (substantially) isolate the RF signal at the node N_{RF} from the low impedance node N_{LF}. Furthermore, the first conduction path (N_{RF}, N_{LF}) may provide an impedance that is sufficiently high at a higher order harmonic frequency range of the RF signal (e.g., including 2f₁ and 2f₂ of FIG. 1C) that may (substantially) isolate the higher order harmonics (e.g., 2f₁ and 2f₂ of FIG. 1C and/or higher order harmonics such as 3f₁, 3f₂, kf₁, kf₂ . . . not shown) of the RF signal that may be present at the node N_{RF} from the low impedance node N_{LF}. As described later in the present disclosure the low impedance node N_{LF} may be provided, for example, by a node carrying a DC voltage, such as the supply voltage (e.g., Vdd) or the reference ground (voltage), or by a low output impedance of a circuit (e.g., a biasing circuit) coupled to, for example, the amplifier stage (110). Accordingly, the low impedance provided by the first conduction path (N_{RF}, N_{LF}) may also allow a DC voltage (i.e., zero frequency) to pass between the two nodes N_{RF} and N_{LF}.

With continued reference to FIG. 2A, the second conduction path (N_{RF}, N_{HF}) may provide an impedance (e.g., tunable impedance) that is sufficiently low at the higher order harmonic frequency range of the RF signal (e.g., including 2f₁ and 2f₂ of FIG. 1C and/or higher order harmonics not shown) that may pass corresponding higher order harmonic frequencies of the RF signal that may be present at the node N_{RF} to the low impedance node N_{HF} substantially unaltered, thereby terminating such harmonics by the low impedance node N_{HF} (e.g., low impedance at the higher order harmonic frequencies). On the other hand, the second conduction path (N_{RF}, N_{HF}) may provide an impedance that is sufficiently high at the frequency range of operation of the RF signal and at the frequency range of the envelope signal that may isolate the RF signal and the envelope signal at the node N_{RF} from the low impedance node N_{HF}. As described later in the present disclosure, the low impedance node N_{HF} may be provided, for example, by the reference ground.

Based on the above description, the multifunctional filter (220) according to the present disclosure may be considered as a (frequency-based) multiplexer that automatically routes specific frequency ranges of an RF signal at the node N_{HF} to one of the two nodes N_{LF} or N_{HF}.

As described above, the node N_{RF} of the multifunctional filter (220) may couple to an RF carrying node of the amplifier stage (110), such as, for example, the input node, N_{IN}, the output node, N_{OUT}, or any other internal node (e.g., any node/terminal of devices/transistors) of the amplifier stage (110). Furthermore, as shown in FIG. 2B and FIG. 2C, several instances (e.g., 220₁, 220₂) of the multifunctional filter (220) may be coupled to different nodes of the amplifier stage (110).

For example, according to the exemplary embodiment of the present disclosure shown in FIG. 2B, a first multifunctional filter (220₁) may be coupled to the input node (N_{IN}, e.g., gate of transistor M1) of the amplifier stage (110) to provide respective first and second conduction paths, (N_{RF1}, N_{LF1}) and (N_{RF1}, N_{HF1}), to the input node, N_{IN}, and a second multifunctional filter (220₂) may be coupled to the output node (N_{OUT}, e.g., drain of an output transistor such as M1 for a case of a single transistor amplifier or Mp of FIG. 1B for a multi-transistor stacked amplifier) of the amplifier stage (110) to provide respective first and second conduction paths, (N_{RF2}, N_{LF2}) and (N_{RF2}, N_{HF2}), to the output node, N_{OUT}.

As another exemplary embodiment of the present disclosure shown in FIG. 2C, a first multifunctional filter (220₁) may be coupled to a gate node (G_{Mk}, e.g., gate of transistor Mk) of a (cascode) transistor of the amplifier stage (110) to provide respective first and second conduction paths, (N_{RF1}, N_{LF1}) and (N_{RF1}, N_{HF1}), to the gate node, G_{Mk}, and a second multifunctional filter (220₂) may be coupled to a drain node (D_{M1}, e.g., drain of transistor M1 or other) of the amplifier stage (110) to provide respective first and second conduction paths, (N_{RF2}, N_{LF2}) and (N_{RF2}, N_{HF2}), to the drain node, D_{M1}.

In some embodiments of the present disclosure, it may be advantageous to couple several instances of the multifunctional filter (e.g., 220) to different (RF carrying) nodes of the amplifier stage (110) that may be as close as possible to a source of nonlinearities presented to the amplifier stage (110). For example, in the case of the configuration (200b) of FIG. 2B, the RF_{IN} signal provided to the input node, N_{IN}, may readily include (higher magnitude unterminated) higher order harmonics and envelope signal from a previous amplification stage, whereas the RF_{OUT} signal provided at the output node, N_{OUT}, may include higher order harmonics generated by the amplifier stage (110). As another example, in the case of the configuration (200c) of FIG. 2C, the RF signal at the drain, D_{M1}, of the transistor M1 may include higher order harmonics and envelope signal included in the input RF signal, RF_{IN}, as well as further higher order harmonics generated by the transistor M1, whereas the gate node, G_{Mk}, may include higher order harmonics and envelope signal coupled through parasitic capacitances inherent to the transistor Mk and which may be further amplified (e.g., current amplification) by the transistor Mk.

In some embodiments of the present disclosure, the node, N_{RF}, of the multifunctional filter may be coupled to an RF node that may further include/carry a DC (e.g., biasing) voltage/current. For example, nodes, N_{OUT}, of FIG. 2B and D_{M1} of FIG. 2C may include a DC biasing voltage/current provided by the supply voltage, Vdd. In such cases, as shown in FIGS. 2B/2C, a DC blocking capacitor (e.g., C_{BL2}, external to block 220₂) coupled between the RF carrying node (e.g., N_{OUT} and D_{M1}) of the amplifier stage (110) and the node (e.g., N_{RF2}) of the multifunctional filter (e.g., 220₂) may be used to block flow of the DC current from the amplifier stage (110) to the low impedance nodes (e.g., N_{LF2} and N_{HF2}). It should be noted that in some configurations of the multifunctional filter according to the present disclosure, the first (e.g., N_{RF}, N_{LF}) and second (e.g., N_{RF}, N_{HF}) conduction paths of the multifunctional filter according to the present teachings may readily include at least one (internal) DC blocking capacitor (e.g., shown in FIGS. 2B/2C as C′_{BL2} inside the block 220₂) that may prevent/block flow of a DC current through such conduction paths, and which may therefore replace functionality of the (external) DC blocking capacitor (e.g., C_{BL2}).

As shown in FIG. 2D, according to an exemplary embodiment of the present disclosure, the low impedance coupled to the low impedance node, N_{LF}, may be provided by an output impedance of a (gate) biasing circuit (e.g., BMk) and the low impedance coupled to the low impedance node, N_{HF}, may be provided by the reference ground. In the configuration (200d) shown in FIG. 2D, because the first conduction path (N_{RF}, N_{LF}) of the multifunctional filter (220) isolates the high frequency components (i.e., RF signal and higher order harmonics) that may be present at the node, N_{RF}, from the node N_{LF}, and therefore from the biasing circuit, BMk, the respective series connected resistor (e.g., one of R1, . . . , Rp of FIG. 1B) described above with reference to the prior art configuration of FIG. 1B may not be used. Naturally, the first conduction path (N_{RF}, N_{LF}) allows the biasing voltage output by the biasing circuit to pass through to the gate node, G_{Mk}.

In an alternative configuration (200c) according to the present disclosure shown in FIG. 2E, the biasing circuit (e.g., BMk) may remain coupled to the gate node, G_{Mk}, via the respective series connected resistor (e.g., Rk), and the low impedance coupled to the low impedance node, NIF, of the multifunctional filter (220) may be provided by the reference ground. Although not shown in FIG. 2E, a DC blocking capacitor (e.g., C_{BL2}, or C′_{BL2}) as described above with reference to FIGS. 2B/2C may be included to not provide a short to a DC voltage/current output by the biasing circuit (e.g., BMk). It should be noted that the configurations (200d) and (200e) described with reference to FIG. 2D and FIG. 2E may be concurrently used with respect to different gate nodes of the amplifier stage (110).

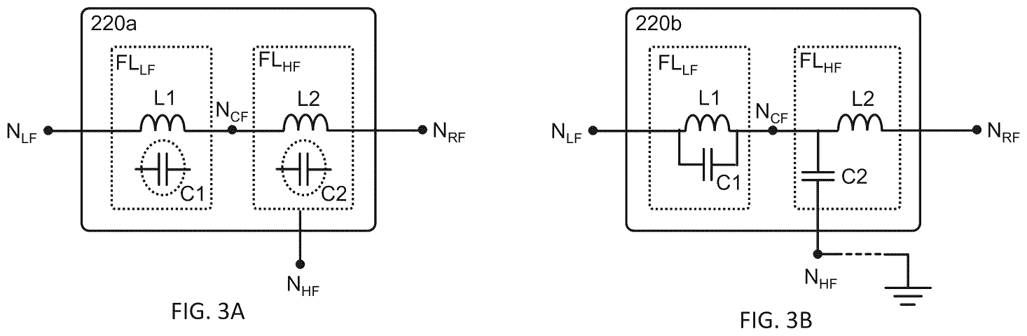

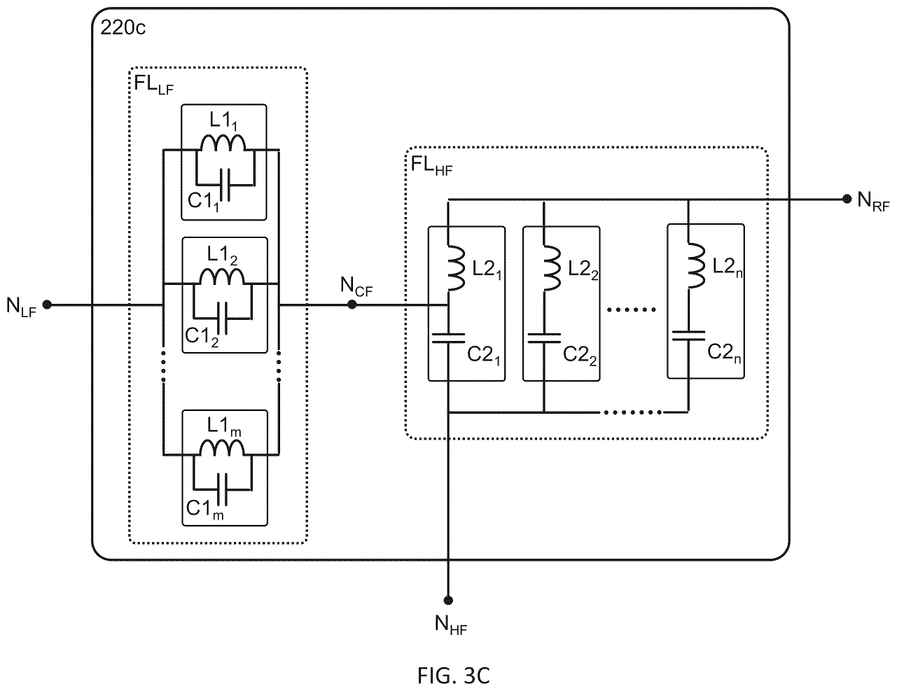

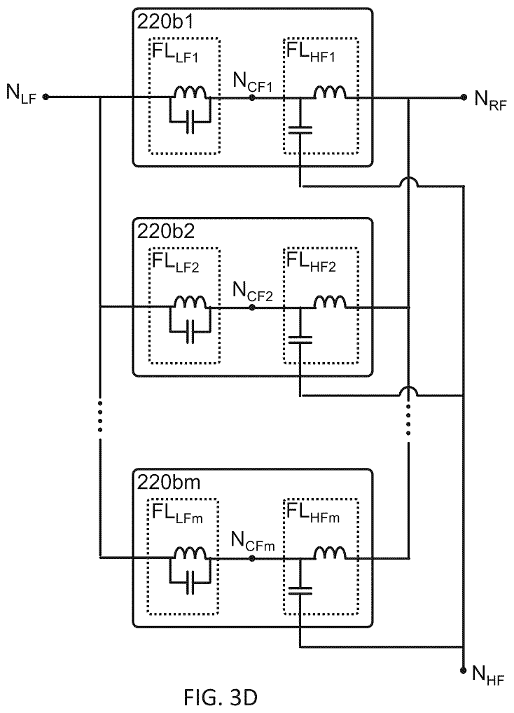

FIG. 3A shows blocks of the multifunctional filter (e.g., 220a) according to the present disclosure. As shown in FIG. 3A, such blocks may include a high frequency filter, FL_{HF}, that comprises an inductor, L2, and a low frequency filter, FL_{LF}, that comprises an inductor, L1. As shown in FIG. 3A, the (series) inductors, L1 and L2, may be arranged in series between the nodes, N_{RF} and N_{LF}, and coupled to one another via a common node, N_{CF}. In other words, the first conduction path (N_{RF}. N_{LF}) of the multifunctional filter (e.g., 220a) according to the present disclosure may be provided by an inductance of the series connected inductors, L1 and L2. Furthermore, as shown in FIG. 3A, according to an embodiment of the present disclosure, the filters, FL_{LF} and FL_{HF}, may be coupled to one another at the common node, N_{CF}. It should be noted that due to the topology of the two filters, FL_{HF} and FL_{LF}, including the arrangement of the two inductors, L1 and L2, the coupling provided by the two filters, FL_{HF} and FL_{LF}, may further be considered as a low pass filter (e.g., L1+L2) arranged between the nodes N_{RF} and N_{LF}.

With continued reference to FIG. 3A, each of the low frequency filter, FL_{LF}, and the high frequency filter, FL_{HF}, may include a at least one respective capacitor, C1 and C2, that in combination with the respective inductor, L1 and L2, may provide the above-described functionality of the respective first (e.g., N_{RF}, N_{LF}) and second (e.g., N_{RF}, N_{HF}) conduction paths. According to an embodiment of the present disclosure, the filters, FL_{LF} and FL_{HF}, may exclusively include (e.g., designed with) reactive components (i.e., inductor, capacitor, L-C filter) and therefore devoid of resistive components (i.e., resistor). According to an embodiment of the present disclosure, the filters, FL_{LF} and FL_{HF}, may be surface acoustic wave (SAW) or bulk acoustic wave (BAW) filters. Realization of the filters according to one or more of an L-C, SAW or BAW filter may be considered a design choice and, in some cases, based on a desired frequency range of operation of the filter.

According to an embodiment of the present disclosure, the low frequency filter, FL_{LF}, may comprise a low pass filter or a bandpass filter (e.g., notch filter, band-reject filter, trap) for the frequency range of the envelope signal. According to an embodiment of the present disclosure, the low frequency filter, FL_{LF}, may comprise a low pass filter or a bandpass filter (e.g., notch filter, band-reject filter, trap) for the frequency range of the envelope signal and including DC (zero frequency). According to an embodiment of the present disclosure, the high frequency filter, FL_{HF}, may comprise a high pass filter or a bandpass filter for the frequency range of the harmonics of the (center frequency of) the RF signal. It should be noted that design and realization of such filters are well known to a person skilled in the art and therefore outside the scope of the present disclosure.

FIG. 3B shows exemplary embodiments according to the present disclosure of the low frequency and high frequency filters, FL_{LF} and FL_{HF}, of FIG. 3A. As shown in FIG. 3B, functionality of the multifunctional filter (e.g., 220b) may be provided by a high frequency filter, FL_{HF}, that may include the inductor L2 and capacitor C2 in series connection between the nodes, N_{RF} and N_{HF}, and low frequency filter, FL_{LF}, that may include the inductor L1 and capacitor C1 in parallel connection between the nodes, N_{CF} and N_{LF}. Accordingly, the second conduction path (N_{RF}, N_{HF}) may be provided by the series connected inductor L2 and capacitor C2. Furthermore, as shown in FIG. 3B, the low impedance to the low impedance node, N_{HF}, may be provided by the reference ground.

With continued reference to FIG. 3B, the high frequency filter (L2, C2) may be described as a trap that shorts the harmonic frequencies components coupled to the node, N_{RF}, to the reference ground, thereby suppressing or otherwise reducing such components. On the other hand, the low frequency filter (L1, C1) may be described as a tank circuit that may be configured to resonate at the frequency range of the harmonics (processed by the filter L2, C2) such to present a high impedance at the common node, N_{CF}, and therefore reduce its influence on operation/performance of the high frequency filter (L2, C2). It should be noted that presence of the parallel connected capacitor, C1, may not influence operation of the first conduction path (N_{RF}, NIF) described above with respect to the lower frequency components (e.g., envelope signal) and higher frequency components (e.g., RF signal and corresponding harmonics). Because the capacitors C1 and C2 target the high frequencies of the harmonics, their capacitances, and therefore physical sizes, may be sufficiently small for integration.

FIG. 3C shows further exemplary embodiments according to the present disclosure of the low frequency and high frequency filters, FL_{LF} and FL_{HF}, of a multifunctional filter (220c). In particular, as shown in FIG. 3C, the high frequency filter, FL_{HF}, may include one or more instances, (L2₁, C2₁), (L2₂, C2₂), . . . , (L2ₙ, C2ₙ), of the trap circuit (L2, C2) described above with reference to FIG. 3B, each coupled between the nodes, N_{FR} and N_{HF}. It should be noted that although the trap circuits (L2₁, C2₁), (L2₂, C2₂), . . . , (L2ₙ, C2ₙ), may be considered arranged in parallel connection, as shown in FIG. 3C only one of the traps (e.g., L2₁, C2₁) may be coupled to the common node, N_{CF}, and therefore to the low frequency filter, FL_{LF}. Accordingly, the one trap that is coupled to the common node, N_{CF}, may be considered as participating (e.g., via a respective inductor, L2₁) in provision of the above-described functionality of the first conduction path (N_{RF}, N_{LF}). Furthermore, the low frequency filter, FL_{LF}, may include one or more instances, (L1₁, C1₁), (L1₂, C1₂), . . . , (L1ₘ, C1ₘ), of the tank circuit (L1, C1) described above with reference to FIG. 3B, each coupled between the nodes, N_{CF} and N_{LF}. Accordingly, all such tank circuits may be considered as participating (e.g., via respective inductors, L1₁, L1₂, . . . L1ₘ) in provision of the above-described functionality of the first conduction path (N_{RF}, N_{LF}).

With further reference to FIG. 3C, the trap circuits (L2₁, C2₁), (L2₂, C2₂), . . . , (L2ₙ, C2ₙ), may be configured to trap (e.g., reject, short) different harmonic frequencies by configuring different trap circuits to pass different frequency ranges corresponding to the different harmonic frequencies. In other words, each of the trap circuits may operate independently to affect (e.g., trap) a different harmonic. According to another embodiment of the present disclosure, a plurality (e.g., group) of the trap circuits (L2₁, C2₁), (L2₂, C2₂), . . . , (L2ₙ, C2ₙ), may be configured to operate in combination to increase performance of the trapping by widening the (passing) frequency range of the trap. In such configuration, the trap circuits may include overlapping (narrower) bandwidths that in combination may provide a wider bandwidth. It should be noted that operation according to both configurations may be provided, wherein the trap circuits may be partitioned as groups of individual or combined traps, each group targeting a specific harmonic frequency range. On the other hand, the tank circuits (L1₁, C1₁), (L1₂, C1₂), . . . , (L1ₘ, C1ₘ), may be configured to operate in combination to increase performance of the tank by widening the frequency range (e.g., resonance) of the tank. It should be noted that the number n of trap circuits and the number m of the tank circuits shown in FIG. 3C may be any integer number equal to, or greater than, one.

FIG. 3D shows an exemplary embodiment of a multifunctional filter (220d) according to the present disclosure based on the configuration of FIG. 3B. As shown in FIG. 3D, the multifunctional filter (220d) may include a plurality of instances (220b1, 220b2, . . . , 220bm) of the multifunctional filter (220b) described above with reference to FIG. 3B, wherein each of the instances may operate, similarly to the multifunctional filter (220c) described above with reference to FIG. 3C, individually to trap a different harmonic frequency and/or in combination to increase performance of the trapping by widening the (passing) frequency range of the trap. It should be noted that differently from the multifunctional filter (220c) of FIG. 3C, the multifunctional filter (220d) may include a plurality of different common nodes, N_{CF1}, N_{CF2} . . . , N_{CFm}, each such common node coupling respective low frequency filters, FL_{LF1}, FL_{LF2} . . . , FL_{LFm}, to respective high frequency filters, FL_{LF1}, FL_{LF2} . . . , FL_{LFm}, of the multifunctional filter (220d).

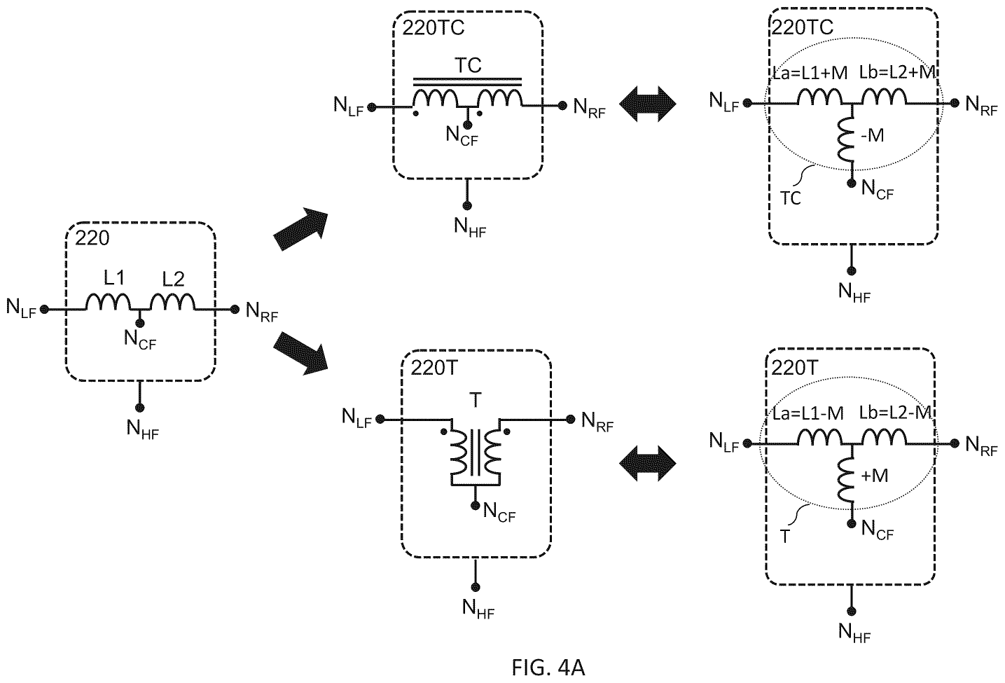

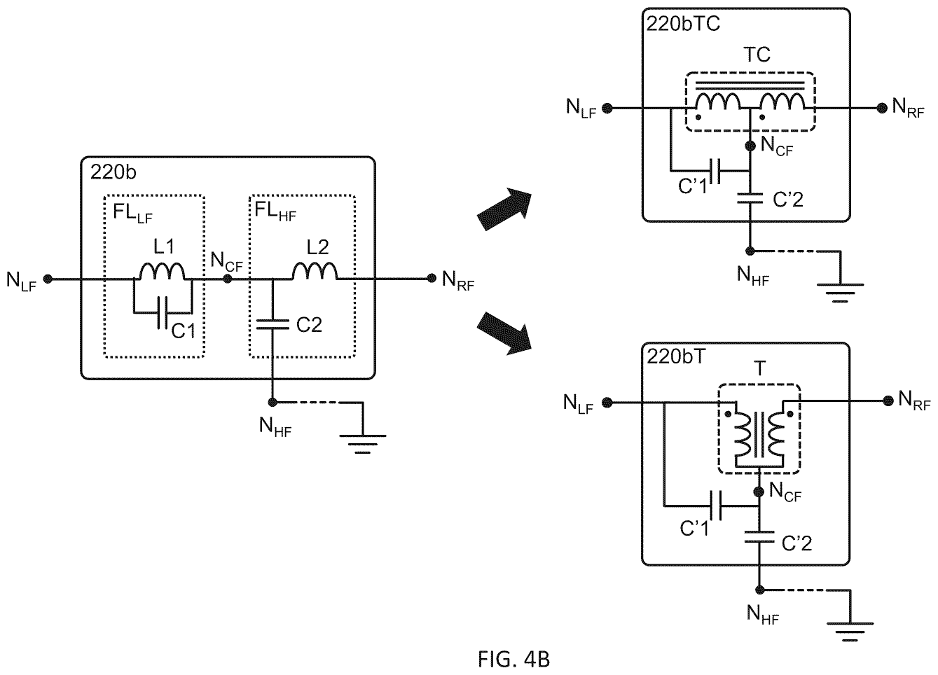

FIG. 4A shows exemplary implementations of two series connected inductors for use as the inductors L1 and L2 of the above-described multifunctional filter (220). As shown in the left side of FIG. 4A, the inductors L1 and L2 may be conventional discrete inductors that may be, for example, laid out in an integrated circuit by known techniques. According to an embodiment of the present disclosure, instead of conventional discrete inductors, the inductors L1 and L2 may be provided by a known in the art T-coil circuit, TC, as shown for the multifunctional filter (220TC) of FIG. 4A or may be provided by a known in the art transformer circuit, T, as shown for the multifunctional filter (220T) of FIG. 4A. Further shown in the far-right side of FIG. 4A are equivalent (impedance/inductance) circuits of the T-coil circuit, TC, and of the transformer circuit, T.

With continued reference to FIG. 4A, each of the T-coil circuit, TC, and the transformer circuit, T, may include inductor coils having (individual) inductances L1 and L2 that are mutually coupled by an inductance having a magnitude M. In the case of the T-coil circuit, TC, the mutually coupled inductance may be negative inductance, −M, and in the case of the transformer circuit, T, the mutually coupled inductance may be a positive inductance, +M. Accordingly, as shown in FIG. 4A, the T-coil circuit, TC, may effectively provide two series connected inductances, La and Lb, having respective inductances equal to L1+M and L2+M, and the transformer circuit, T, may effectively provide two series connected inductances, La and Lb, having respective inductances equal to L1−M and L2−M.

FIG. 4B shows the exemplary implementations of the two series connected inductors according to FIG. 4A applied to the exemplary multifunctional filter of FIG. 3B. Because for same inductor coils (e.g., L1 and L2), the T-coil circuit, TC, of the multifunctional filter (220bTC) shown in the top right side of FIG. 4B may provide a larger effective series connected inductance (e.g., La+Lb=L1+L2+2M of FIG. 4A), increased impedance at the center frequency (e.g., f₀ of FIG. 1C) of the RF signal (e.g., f₀ of FIG. 1C) may be provided for an increased isolation of the center frequency between the nodes N_{RF} and N_{LF}. Furthermore, due to the presence of the negative mutual inductance (e.g., −M of FIG. 4A) that couples each of the series inductances (e.g., La and Lb of FIG. 4A) to the common node, N_{CF}, the capacitors, C′1 and C′2, of the multifunctional filter (220bTC) may include larger sizes (capacitances) when compared to the capacitors C1 and C2 of the multifunctional filter (220b) shown in the left side of FIG. 4B. Such larger size capacitances may in turn provide a wider bandwidth of operation of the respective higher harmonics trap circuit (e.g., provided by Lb−M and C′2) and tank circuit (e.g., provided by La−M and C′1). On the other hand, considering the multifunctional filter (220bT) shown in the bottom right side of FIG. 4B, the transformer circuit, T, may provide a smaller effective series connected inductance (e.g., La+Lb=L1+L2−2M), and therefore a reduced impedance at the frequencies of the envelope signal which may result in an improved performance (e.g., rejection of the envelope signal at the node N_{RF}) when compared to the multifunctional filter (220b).

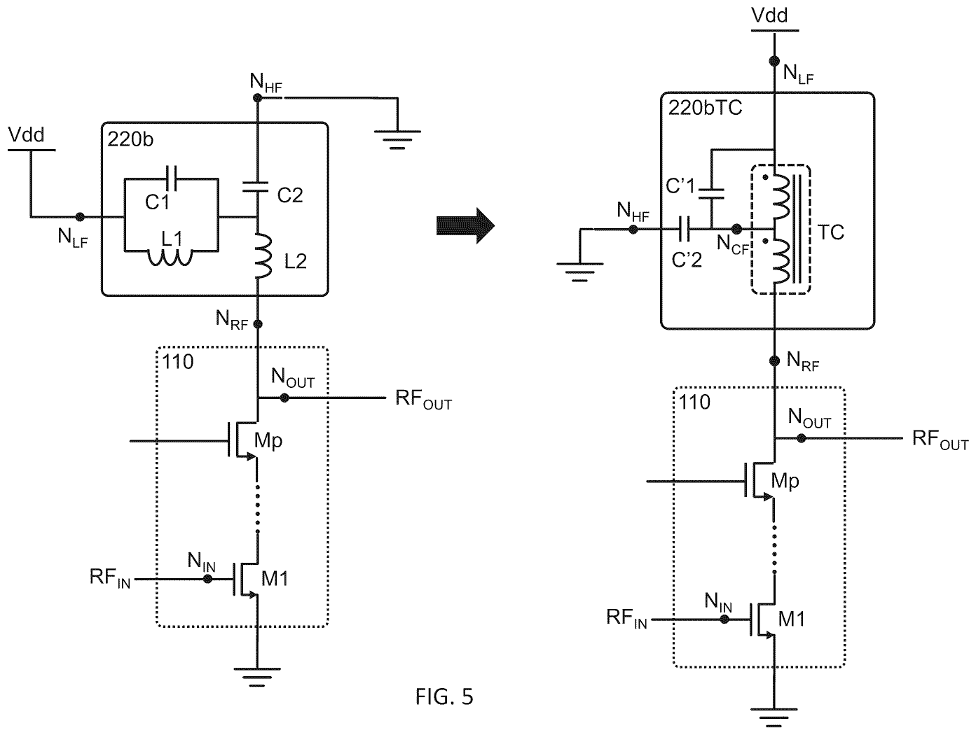

FIG. 5 show simplified schematics of a multifunctional filter (e.g., 220b, 220bTC) of FIG. 4B configured to couple the output node, N_{OUT}, of the amplifier stage (110) exemplary low impedance nodes (e.g., Vdd and reference ground). In particular, shown in the left side of FIG. 5, the node N_{RF} of the multifunctional filter (220b) couples the output node, N_{OUT}, of the amplifier stage (110) and the nodes N_{LF} and N_{HF} of the multifunctional filter (220b) respectively couple to the supply voltage, Vdd, and the reference ground. In such configuration, the supply voltage, Vdd, may couple to the amplifier stage (110) through the series connected inductors, L1 and L2, while a DC path from the output node, N_{OUT}, to the reference ground may be blocked by the capacitor C2. Shown in the right side of FIG. 5 is an equivalent configuration for the case of the multifunctional filter (220bTC).

It should be noted that teachings according to the present disclosure may not be limited to an amplifier stage (e.g., 110 of FIG. 2A) that includes one or more FET devices (e.g., M1 of FIG. 2A), rather the present teachings my apply to amplifier stages that include other device types, including, for example, bipolar devices (e.g., GaAs transistors). Furthermore, the present teachings may apply to multistage or cascaded amplifier configurations that may use multiple instances of an amplifier stage similar to the amplifier stage (110) of FIG. 2A in series connection, one or more of the stages including the described multifunctional filter(s). In some configurations, each stage of the multiple stages may be simultaneously active, and in some configurations each stage of the multiple stages may be selectively active. Furthermore, each stage of the multiple stages may be configured to (selectively) operate at one or more center frequencies (e.g., channels, modes) and the respective multifunctional filters may be tunable to operate according to the respective center frequencies. Tunability of the multifunctional filters may be provided by tunable elements (e.g., tunable/selectable/variable/configurable inductors and/or capacitors) and/or switchable multifunctional filters (e.g., switch in/out one of a plurality of multifunctional filters according to a center frequency of operation).

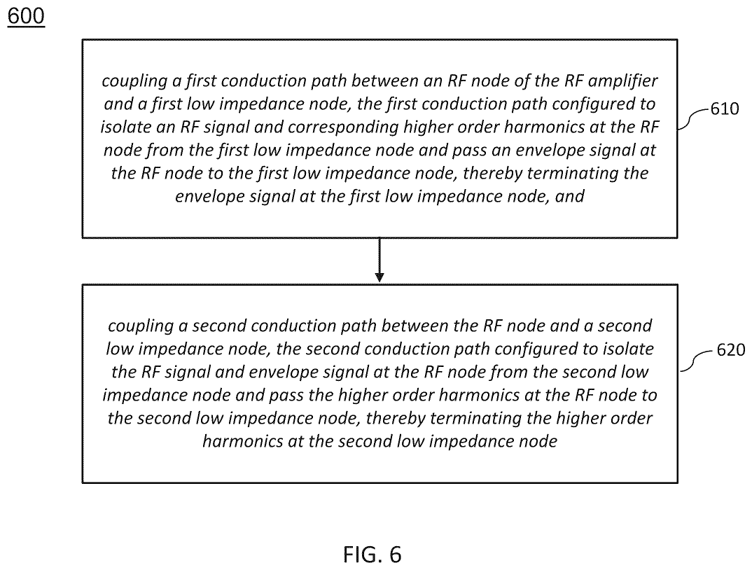

FIG. 6 is a process chart (600) showing various steps of a method for reducing intermodulation distortion products in a radio frequency (RF) amplifier. As can be seen in the process chart (600), the method comprises: coupling a first conduction path between an RF node of the RF amplifier and a first low impedance node, the first conduction path configured to isolate an RF signal and corresponding higher order harmonics at the RF node from the first low impedance node and pass an envelope signal at the RF node to the first low impedance node, thereby terminating the envelope signal at the first low impedance node, per step (610), and coupling a second conduction path between the RF node and a second low impedance node, the second conduction path configured to isolate the RF signal and envelope signal at the RF node from the second low impedance node and pass the higher order harmonics at the RF node to the second low impedance node, thereby terminating the higher order harmonics at the second low impedance node, per step (630), thereby reducing the intermodulation distortion products based on the terminating of the envelope signal and the terminating of the higher order harmonics.

Applications that may include the novel apparatus and systems of various embodiments include electronic circuitry used in high-speed computers, communication and signal processing circuitry, modems, single or multi-processor modules, single or multiple embedded processors, data switches, and application-specific modules, including multilayer, multi-chip modules. Such apparatus and systems may further be included as sub-components within a variety of electronic systems, such as televisions, cellular telephones, personal computers (e.g., laptop computers, desktop computers, handheld computers, tablet computers, etc.), workstations, radios, video players, audio players (e.g., mp3 players), vehicles, medical devices (e.g., heart monitor, blood pressure monitor, etc.) and others. Some embodiments may include a number of methods.

The term “MOSFET” technically refers to metal-oxide-semiconductor-field-effect-transistors; another synonym for MOSFET is “MISFET”, for metal-insulator-semiconductor FET. However, “MOSFET” has become a common label for most types of insulated-gate FETs (“IGFETs”). Despite that, it is well known that the term “metal” in the names MOSFET and MISFET is now often a misnomer because the previously metal gate material is now often a layer of polysilicon (polycrystalline silicon). Similarly, the “oxide” in the name MOSFET can be a misnomer, as different dielectric materials are used with the aim of obtaining strong channels with smaller applied voltages. Accordingly, the term “MOSFET” as used herein is not to be read as literally limited to metal-oxide-semiconductor FETs, but instead includes IGFETs in general.

As should be readily apparent to one of ordinary skill in the art, various embodiments of the invention can be implemented to meet a wide variety of specifications. Unless otherwise noted above, selection of suitable component values is a matter of design choice and various embodiments of the invention may be implemented in any suitable IC technology (including but not limited to MOSFET and IGFET structures), or in hybrid or discrete circuit forms. Integrated circuit embodiments may be fabricated using any suitable substrates and processes, including but not limited to standard bulk silicon, silicon-on-insulator (SOI), silicon-on-sapphire (SOS), GaN HEMT, GaAs pHEMT, and MESFET technologies. However, the inventive concepts described above are particularly useful with an SOI-based fabrication process (including SOS), and with fabrication processes having similar characteristics. Fabrication in CMOS on SOI or SOS enables low power consumption, the ability to withstand high power signals during operation due to FET stacking, good linearity, and high frequency operation (in excess of about 10 GHZ, and particularly above about 20 GHZ). Monolithic IC implementation is particularly useful since parasitic capacitances generally can be kept low (or at a minimum, kept uniform across all units, permitting them to be compensated) by careful design.

Voltage levels may be adjusted or voltage and/or logic signal polarities reversed depending on a particular specification and/or implementing technology (e.g., NMOS, PMOS, or CMOS, and enhancement mode or depletion mode transistor devices). Component voltage, current, and power handling capabilities may be adapted as needed, for example, by adjusting device sizes, serially “stacking” components (particularly FETs) to withstand greater voltages, and/or using multiple components in parallel to handle greater currents. Additional circuit components may be added to enhance the capabilities of the disclosed circuits and/or to provide additional functions without significantly altering the functionality of the disclosed circuits.

The examples set forth above are provided to give those of ordinary skill in the art a complete disclosure and description of how to make and use the embodiments of the gate drivers for stacked transistor amplifiers of the disclosure and are not intended to limit the scope of what the applicant considers to be the invention. Such embodiments may be, for example, used within mobile handsets for current communication systems (e.g., WCDMA, LTE, 5G-NR, WiFi, etc.) wherein amplification of signals with frequency content of above 100 MHz and at power levels of above 50 mW may be required. The skilled person may find other suitable implementations of the presented embodiments.

Modifications of the above-described modes for carrying out the methods and systems herein disclosed that are obvious to persons of skill in the art are intended to be within the scope of the following claims. All patents and publications mentioned in the specification are indicative of the levels of skill of those skilled in the art to which the disclosure pertains. All references cited in this disclosure are incorporated by reference to the same extent as if each reference had been incorporated by reference in its entirety individually.

It is to be understood that the disclosure is not limited to particular methods or systems, which can, of course, vary. It is also to be understood that the terminology used herein is for the purpose of describing particular embodiments only and is not intended to be limiting. As used in this specification and the appended claims, the singular forms “a”, “an”, and “the” include plural referents unless the content clearly dictates otherwise. The term “plurality” includes two or more referents unless the content clearly dictates otherwise. Unless defined otherwise, all technical and scientific terms used herein have the same meaning as commonly understood by one of ordinary skill in the art to which the disclosure pertains.

A number of embodiments of the disclosure have been described. Nevertheless, it will be understood that various modifications can be made without departing from the spirit and scope of the present disclosure. Accordingly, other embodiments are within the scope of the following claims.

1. A circuit, comprising:
a radio frequency (RF) amplifier configured to amplify an RF signal; and
a multifunctional filter coupled to an RF node of the RF amplifier, wherein the multifunctional filter comprises:
a first conduction path between the RF node and a first low impedance node, the first conduction path configured to isolate the RF signal and corresponding higher order harmonics at the RF node from the first low impedance node and pass an envelope signal at the RF node to the first low impedance node; and
a second conduction path between the RF node and a second low impedance node, the second conduction path configured to isolate the RF signal and envelope signal at the RF node from the second low impedance node and pass the higher order harmonics at the RF node to the second low impedance node.

2. The circuit according to claim 1, wherein:
the first conduction path comprises first and second inductors in series connection.

3. The circuit according to claim 2, wherein:
the first and second inductors in series connection form a low pass filter that passes the envelope signal.

4. The circuit according to claim 2, wherein the first and second inductors are mutually coupled inductors provided by a T-coil circuit.

5. The circuit according to claim 2, wherein the first and second inductors are mutually coupled inductors provided by a transformer circuit.

6. The circuit according to claim 2, wherein the second conduction path comprises the second inductor in series connection with a second capacitor.

7. The circuit according to claim 6, wherein the second inductor in series connection with the second capacitor forms a high pass or band pass filter that passes the higher order harmonics.

8. The circuit according to claim 7, wherein the band pass filter is a trap circuit at a frequency of the higher order harmonics, the higher order harmonics including a second harmonic.

9. The circuit according to claim 8, wherein the multifunctional filter further comprises additional one or more trap circuits at respective one or more frequencies of the higher order harmonics.

10. The circuit according to claim 7, wherein the multifunctional filter further comprises a first capacitor in parallel connection with the first inductor.

11. The circuit according to claim 10, wherein the first capacitor in parallel connection with the first inductor forms a tank circuit that resonates at the higher order harmonics, the higher order harmonics including a second harmonic.

12. The circuit according to claim 11, wherein the multifunctional filter further comprises additional one or more tank circuits that resonate at the respective one or more frequencies of the higher order harmonics.

13. The circuit according to claim 1, wherein the multifunctional filter further comprises:
additional one more first conduction paths between the RF node and respective additional first low impedance nodes, each additional first conduction path configured to isolate the RF signal and the higher order harmonics at the RF node from the respective additional first low impedance node and pass the envelope signal at the RF node to the respective additional first low impedance node; and
additional one or more second conduction paths between the RF node and respective additional second low impedance nodes, each additional second conduction path configured to isolate the RF signal and the envelope signal at the RF node from the respective additional second low impedance node and pass the higher order harmonics at the RF node to the respective additional second low impedance node.

14. The circuit according to claim 1, wherein:
the RF amplifier comprises an input transistor configured to receive the RF signal at an input node of the input transistor, and
the RF node is the input node.

15. The circuit according to claim 14, wherein:
the input transistor is configured to receive an input biasing voltage at the input node, the input biasing voltage coupled to the input node through the first conduction path.

16. The circuit according to claim 15, further comprising an input transistor biasing circuit configured to generate the input biasing voltage at a low impedance output node of the input transistor biasing circuit, wherein the first low impedance node is coupled to the low impedance output node.

17. The circuit according to claim 14, wherein:
the input transistor is configured to receive an input biasing voltage at the input node, the input biasing voltage coupled to the input node through a resistor.

18. The circuit according to claim 14, wherein:
the RF amplifier further comprises an additional transistor coupled to the input transistor,
the circuit further comprises an additional multifunctional filter coupled to the additional transistor at an additional RF node, the additional multifunctional filter comprising:
an additional first conduction path between the additional RF node and an additional first low impedance node, the additional first conduction path configured to isolate the RF signal and the higher order harmonics at the additional RF node from the additional first low impedance node and pass the envelope signal at the additional RF node to the additional first low impedance node; and
an additional second conduction path between the additional RF node and an additional second low impedance node, the additional second conduction path configured to isolate the RF signal and the envelope signal at the additional RF node from the additional second low impedance node and pass the higher order harmonics at the additional RF node to the additional second low impedance node.

19. The circuit according to claim 14, wherein:
the additional RF node carries a DC voltage, and
the additional multifunctional filter is coupled to the additional RF node through a capacitor.

20. The circuit according to claim 14, wherein:
the additional RF node is coupled to a DC voltage provided through the first conduction path, and
the second conduction path comprises a capacitor that blocks conduction of a DC current from the additional RF node to the second low impedance node.

21. The circuit according to claim 1, wherein:
the first low impedance node is a node that carries a supply voltage to the RF amplifier, and
the second low impedance node is a node at a reference ground.

22. The circuit according to claim 1, wherein:
the first low impedance node is a node at a reference ground, and
the second low impedance node is a node at the reference ground.

23. A method for reducing intermodulation distortion products in a radio frequency (RF) amplifier, the method comprising:
coupling a first conduction path between an RF node of the RF amplifier and a first low impedance node, the first conduction path configured to isolate an RF signal and corresponding higher order harmonics at the RF node from the first low impedance node and pass an envelope signal at the RF node to the first low impedance node, thereby terminating the envelope signal at the first low impedance node; and
coupling a second conduction path between the RF node and a second low impedance node, the second conduction path configured to isolate the RF signal and envelope signal at the RF node from the second low impedance node and pass the higher order harmonics at the RF node to the second low impedance node, thereby terminating the higher order harmonics at the second low impedance node;
thereby reducing the intermodulation distortion products based on the terminating of the envelope signal and the terminating of the higher order harmonics.

24. The method according to claim 23, wherein:
the higher order harmonics include second harmonics, and
the terminating of the higher order harmonics includes shorting of the second harmonics to a reference ground coupled to the second low impedance node.
